(19) United States
(12) Patent Application Publication
(10) Pub. No.: US 2025/0151473 A1
(43) Pub. Date: May 8, 2025

(54) DISPLAY DEVICE

(71) Applicant: LG Display Co., Ltd., Seoul (KR)

(72) Inventors: YongSeok KWAK, Paju-si (KR); SeungJun LEE, Paju-si (KR); Yuseop SHIN, Bucheon-si (KR)

(73) Assignee: LG Display Co., Ltd., Seoul (KR)

(21) Appl. No.: 18/821,206

(22) Filed: Aug. 30, 2024

(30) Foreign Application Priority Data
Nov. 7, 2023 (KR) 10-2023-0152604

(51) Int. Cl. H01L 33/38; H01L 25/075; H01L 25/16; H01L 33/40; H01L 33/62

(52) U.S. Cl. CPC H10H 20/8312; H01L 25/0753; H01L 25/167; H10H 20/835; H10H 20/857

(57) ABSTRACT

A display device may include a substrate, pixels including sub-pixels, a first cover layer which is disposed on the substrate and includes an open area, a plurality of first light emitting diodes which is disposed at the sub-pixels on the first cover layer, and a second light emitting diode, which is disposed in one or more pixels among the pixels, on the substrate. A part of a lower side of the second light emitting diode may be disposed in the open area. A part of an upper side of the second light emitting diode may be disposed on the first cover layer. An area of a top surface of the second light emitting diode may be larger than an area of a bottom surface of the second light emitting diode. A repair light emitting diode is transferred only when a defect occurs, thereby reducing a process cost.

### CROSS-REFERENCE TO RELATED APPLICATIONS

This application claims the benefit of and priority to Korean Patent Application No. 10-2023-0152604 filed on Nov. 7, 2023, the entirety of which is incorporated herein by reference for all purposes.

### BACKGROUND

### 1. Technical Field

The present disclosure relates to a display device, and more particularly to, for example, without limitation, a display device using a light emitting diode (LED).

### 2. Description of the Related Art

Display devices may be used for, among others, a computer monitor, a television, a cellular phone, and the like, and a display device may employ, for example, an organic light emitting display (OLED) device which is a self-emitting device, a liquid crystal display (LCD) device which requires a separate light source, or the like.

An applicable range of the display device is diversified to personal digital assistants as well as monitors of computers and televisions, and a display device with a large display area and a reduced volume and weight is being studied.

Further, recently, a display device including a light emitting diode is attracting attention as a next generation display device. Since the light emitting diode is formed of an inorganic material, rather than an organic material, reliability is excellent so that a lifespan thereof is longer than that of the liquid crystal display device or the organic light emitting display device. Further, the light emitting diode has a fast lighting speed, excellent luminous efficiency, and a strong impact resistance so that a stability is excellent and an image having a high luminance can be displayed.

The description of the related art should not be assumed to be prior art merely because it is mentioned in or associated with this section. The description of the related art includes information that describes one or more aspects of the subject technology, and the description in this section does not limit the invention.

### SUMMARY

In one or more aspects, an object to be achieved by the present disclosure is to provide a display device in which a repair light emitting diode is transferred only when a defect occurs, thereby reducing a process cost.

In one or more aspects, another object to be achieved by the present disclosure is to provide a display device in which a reflection layer is disposed on a side surface of a repair light emitting diode to suppress degradation of a luminance.

Objects of the present disclosure are not limited to the above-mentioned objects, and other objects, which are not mentioned above, can be clearly understood by those skilled in the art from the following descriptions.

According to one or more aspects of the present disclosure, there is provided a display device. The display device comprises a substrate, a plurality of pixels including a plurality of sub-pixels, a first cover layer which is disposed on the substrate and includes an open area, a plurality of first light emitting diodes which is disposed at the plurality of sub-pixels on the first cover layer and a second light emitting diode, which is disposed in one or more pixels among the plurality of pixels, on the substrate, wherein a part of a lower side of the second light emitting diode is disposed in the open area, a part of an upper side of the second light emitting diode is disposed on the first cover layer, and an area of a top surface of the second light emitting diode is larger than an area of a bottom surface of the second light emitting diode.

According to one or more aspects of the present disclosure, there is provided a display device. The display device comprises a substrate, a plurality of pixels including a plurality of sub-pixels, a plurality of first light emitting diodes disposed on the substrate, each of the plurality of first light emitting diodes being disposed in a respective one of the plurality of sub-pixels, and a second light emitting diode disposed on the substrate, the second light emitting diode being disposed in one or more pixels among the plurality of pixels, wherein a top layer of each of the plurality of first light emitting diodes comprises a conductive electrode, and a top layer of the second light emitting diode comprises a semiconductor layer and excludes a conductive electrode.

Other detailed matters of example embodiments are included in the detailed description and the drawings.

According to one or more aspects of the present disclosure, a repair light emitting diode is transferred only when a defect occurs in a specific sub-pixel to reduce a manufacturing cost of a display device.

According to one or more aspects of the present disclosure, a stepped structure is formed on a planarization layer to easily repair the light emitting diode.

According to one or more aspects of the present disclosure, a light emitting diode is disposed in a stepped structure of a planarization layer to suppress the short circuit between light emitting diode electrodes.

According to one or more aspects of the present disclosure, a reflective material is disposed on a side surface of a planarization layer which encloses an emission layer to improve luminance.

The effects according to one or more aspects of the present disclosure are not limited to the foregoing, and other additional effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a schematic diagram of a display device according to an example embodiment of the present disclosure;

FIG. 2 is an enlarged plan view of a display device according to an example embodiment of the present disclosure;

FIG. 3 is an example of a cross-sectional view taken along A-A′ of FIG. 2;

FIG. 4 is an enlarged plan view a state before repairing a display device according to an example embodiment of the present disclosure;

FIG. 5 is an example of a cross-sectional view taken along B-B′ of FIG. 4;

FIGS. 6A to 6G are process diagrams for explaining a forming process of a display device according to an example embodiment of the present disclosure;

FIG. 7 is an enlarged plan view of a display device according to another example embodiment of the present disclosure;

FIG. 8 is an example of a cross-sectional view taken along C-C′ of FIG. 7;

FIG. 9 is an enlarged plan view of a display device according to still another example embodiment of the present disclosure; and

FIG. 10 is an example of a cross-sectional view taken along D-D′ of FIG. 9.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

Hereinafter, a display device according to one or more example embodiments of the present disclosure will be described in more detail with reference to accompanying drawings.

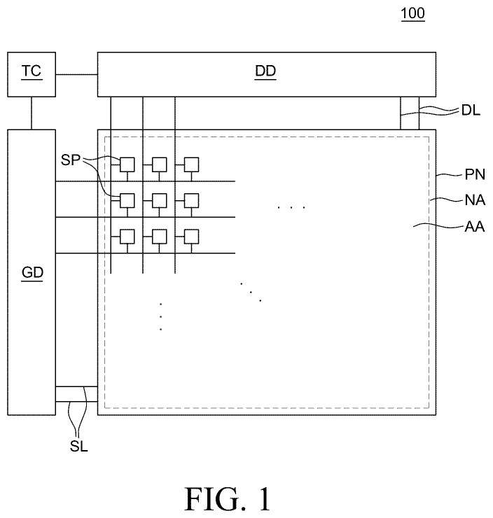

FIG. 1 is a schematic diagram of a display device according to an example embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub-pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub-pixels SP. In the display panel PN, the plurality of scan lines SL and the plurality of data lines DL intersect each other and the plurality of sub-pixels SP is connected to the scan lines SL and the data lines DL, respectively. In addition, even though it is not illustrated in the drawing, each of the plurality of sub-pixels SP is connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub-pixels SP which configures a plurality of pixels PX and a circuit for driving the plurality of sub-pixels SP may be disposed. The plurality of sub-pixels SP is a minimum unit which configures the active area AA and n sub-pixels SP form one pixel PX. In each of the plurality of sub-pixels SP, a light emitting diode and a thin film transistor for driving the light emitting diode may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro LED).

In the active area AA, a plurality of signal lines which transmits various signals to the plurality of sub-pixels SP is disposed. For example, the plurality of signal lines may include a plurality of data lines DL which supplies a data voltage to each of the plurality of sub-pixels SP and a plurality of scan lines which supplies a gate voltage to each of the plurality of sub-pixels SP. The plurality of scan lines SL extends to one direction in the active area AA to be connected to the plurality of sub-pixels SP and the plurality of data lines DL extends to a direction different from the one direction in the active area AA to be connected to the plurality of sub-pixels SP. In addition, in the active area AA, a low potential power line and a high potential power line may be further disposed, but are not limited thereto.

The non-active area NA is an area where images are not displayed so that the non-active area NA may be defined as an area extending from the active area AA. In the non-active area NA, a link line which transmits a signal to the sub-pixel SP of the active area AA, a pad electrode, or a driving IC, such as a gate driver IC or a data driver IC, may be disposed. The non-active area NA may be located on a rear surface of the display panel PN, that is, a surface on which the sub-pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub-pixels SP in the active area AA in a gate in active area (GIA) manner. For example, the data driver DD and the timing controller TC are formed in separate flexible film and printed circuit board and may be electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, a bezel is increased.

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel with substantially no bezel may be implemented.

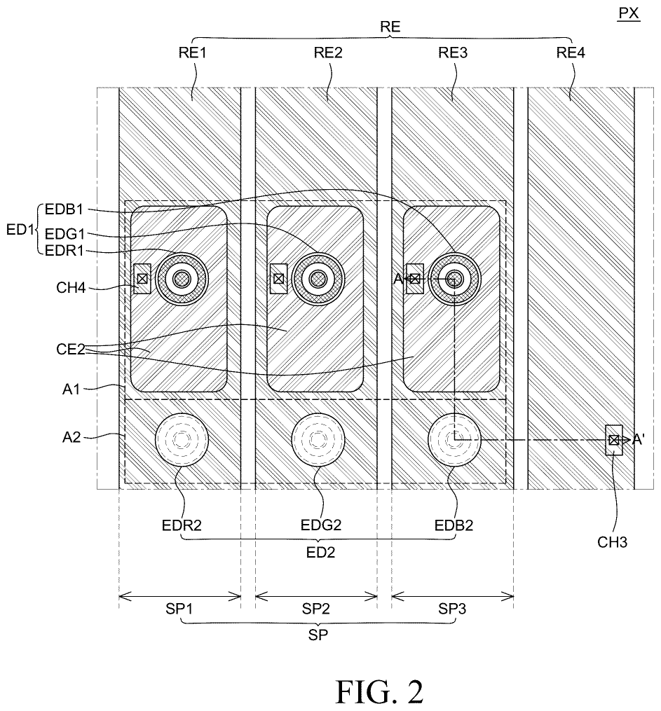

FIG. 2 is a schematic enlarged plan view of a display device according to an example embodiment of the present disclosure. For the convenience of illustration, in FIG. 2, only a plurality of sub-pixels SP, a plurality of reflective electrodes RE, a plurality of first light emitting diodes ED1, a plurality of second light emitting diodes ED2, a first area A1, a second area A2, and a second connection electrode CE2 are illustrated.

First, referring to FIG. 2, the display panel PN includes a plurality of pixels PX which is formed by a plurality of sub-pixels SP. Each of the plurality of sub-pixels SP includes a light emitting element ED and a pixel circuit to independently emit light. One pixel PX may include one or more first sub-pixels SP1, one or more second sub-pixels SP2, and one or more third sub-pixels SP3. For example, the first sub-pixel SP1 is a red sub-pixel, the second sub-pixel SP2 is a green sub-pixel, and the third sub-pixel SP3 is a blue sub-pixel, but it is not limited thereto.

Each of the plurality of sub-pixels SP may include the first area A1 and the second area A2. In the first area A1 and the second area A2 of the plurality of sub-pixels SP, a plurality of light emitting diodes ED including the plurality of first light emitting diodes ED1 and the plurality of second light emitting diodes ED2 may be disposed.

In the first area A1 of the plurality of sub-pixels SP, the plurality of first light emitting diodes ED1, among the plurality of light emitting diodes ED, is disposed.

The plurality of first light emitting diodes ED1 is light emitting diodes which are transferred onto a substrate when a display device is initially manufactured. That is, regardless of the defect of the plurality of first light emitting diodes ED1, the plurality of first light emitting diodes ED1 is disposed in each of the plurality of sub-pixels SP. Therefore, the first light emitting diode ED1 may be referred to as a main light emitting diode.

The plurality of first light emitting diodes ED1 includes a first red light emitting diode EDR1, a first green light emitting diode EDG1, and a first blue light emitting diode EDB1. The first red light emitting diode EDR1 is disposed in the first sub-pixel SP1, the first green light emitting diode EDG1 is disposed in the second sub-pixel SP2, and the first blue light emitting diode EDB1 may be disposed in the third sub-pixel SP3.

In the second area A2 of the plurality of sub-pixels SP, the plurality of second light emitting diodes ED2, among the plurality of light emitting diodes ED, is disposed.

The plurality of second light emitting diodes ED2 are normal (or functional or operational) light emitting diodes, and the first light emitting diode ED1 disposed in the same sub-pixel as the second light emitting diode ED2 may be a defective light emitting diode. For example, the plurality of second light emitting diodes ED2 is light emitting diodes which are transferred onto the substrate when a defective light emitting diode occurs among the plurality of first light emitting diodes ED1, or the first light emitting diode ED1 does not or cannot emit light (or emits weak light) due to a failure in an electrical connection to the first light emitting diode ED1 even though the first light emitting diode ED1 itself is not defective. Therefore, the plurality of second light emitting diode ED2 may be referred to as repair light emitting diodes. In FIG. 2, it is assumed that all the plurality of first light emitting diodes ED1 does not emit light due to the above-described reasons of defect so that the plurality of second light emitting diodes ED2 is transferred to all the plurality of sub-pixels SP.

The plurality of second light emitting diodes ED2 includes a second red light emitting diode EDR2, a second green light emitting diode EDG2, and a second blue light emitting diode EDB2. The second red light emitting diode EDR2 is disposed in the first sub-pixel SP1, the second green light emitting diode EDG2 is disposed in the second sub-pixel SP2, and the second blue light emitting diode EDB2 may be disposed in the third sub-pixel SP3.

Therefore, as illustrated in FIG. 2, in the first sub-pixel SP1, the first red light emitting diode EDR1 and the second red light emitting diode EDR2 are disposed. In the second sub-pixel SP2, the first green light emitting diode EDG1 and the second green light emitting diode EDG2 are disposed. In the third sub-pixel SP3, the first blue light emitting diode EDB1 and the second blue light emitting diode EDB2 may be disposed.

At this time, as described above, in FIG. 2, it is illustrated that all the plurality of first light emitting diodes ED1 is defective so that one second light emitting diode ED2 is disposed in each of the plurality of sub-pixels SP. However, it is not limited thereto, and the second light emitting diode ED2 may be disposed only in some sub-pixel SP in which the first light emitting diode ED1 is defective, among the plurality of sub-pixels SP. For example, when among the plurality of first light emitting diodes ED1, only the first blue light emitting diode EDB1 is defective (so that it does not or cannot emit light, or it can emit weak light), the second light emitting diode ED2 may be disposed only in the third sub-pixel SP3, among the plurality of sub-pixels SP. In this case, one pixel PX is configured by a first sub-pixel SP1 in which the first red light emitting diode EDR1 is disposed, a second sub-pixel SP2 in which the first green light emitting diode EDG1 is disposed, and a third sub-pixel SP3 in which the first blue light emitting diode EDB1 and the second blue light emitting diode EDB2 are disposed.

In the meantime, the second light emitting diode ED2 may have an inverted structure of the first light emitting diode ED1. That is, the first light emitting diode ED1 and the second light emitting diode ED2 are formed with the same configuration, but on the cross-section, a laminating order of the second light emitting diode ED2 may be opposite to a laminating order of the first light emitting diode ED1.

In the meantime, even though it is not illustrated in FIG. 2, a driving transistor may be disposed in each of the first sub-pixel SP1, the second sub-pixel SP2, and the third sub-pixel SP3. For example, the driving transistor may include a first driving transistor disposed in the first sub-pixel SP1, a second driving transistor disposed in the second sub-pixel SP2, and a third driving transistor disposed in the third sub-pixel SP3.

At this time, when both the first light emitting diode ED1 and the second light emitting diode ED2 are disposed in one sub-pixel SP, the first light emitting diode ED1 and the second light emitting diode ED2 may be connected to the same driving transistor. Therefore, light emitting diodes ED disposed in the same sub-pixel SP, among the plurality of light emitting diodes ED, may be driven by the same driving transistor.

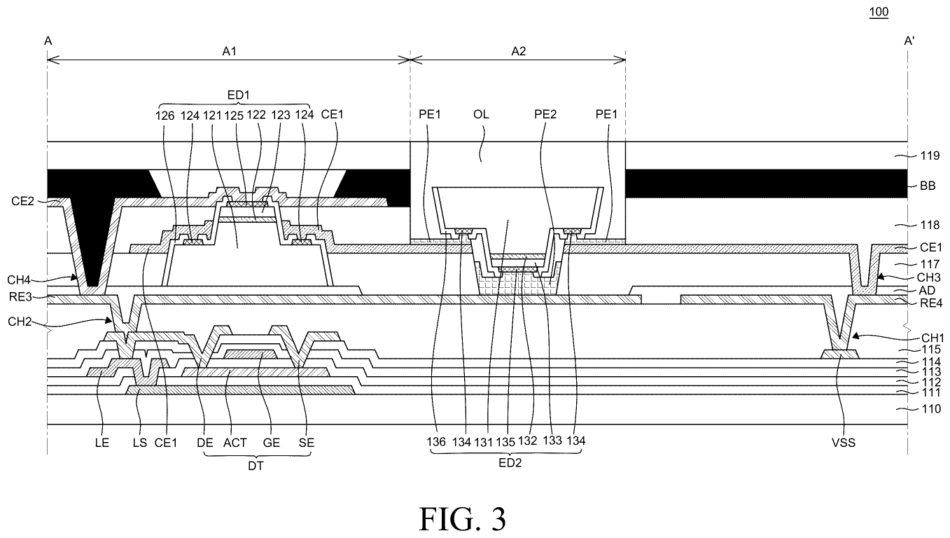

Hereinafter, the first light emitting diode ED1 and the second light emitting diode ED2 will be described in more detail with reference to FIG. 3 together with FIG. 2.

FIG. 3 is an example of a cross-sectional view taken along A-A′ of FIG. 2. Referring to FIG. 3, in each of the plurality of sub-pixels SP of the display panel PN of the display device 100 according to the example embodiment of the present disclosure, a substrate 110, a buffer layer 111, a gate insulating layer 112, a first interlayer insulating layer 113, a second interlayer insulating layer 114, a first planarization layer 115, an adhesive layer AD, a first cover layer 117, a second cover layer 118, a protection layer OL, a driving transistor DT, a light emitting diode ED, a plurality of reflective electrodes RE, a plurality of connection electrodes CE, a first conductive pattern PE1, a second conductive pattern PE2, a power line VSS, a light shielding layer LS, and an auxiliary electrode LE are disposed.

First, the substrate 110 is a component for supporting various components included in the display device 100 and may be formed of an insulating material. For example, the substrate 110 may be formed of glass or resin. Further, the substrate 110 may be configured to include polymer or plastics or may be formed of a material having flexibility.

The light shielding layer LS is disposed in each of the plurality of sub-pixels SP on the substrate 110. The light shielding layer LS blocks light incident onto an active layer ACT of the driving transistor DT to be described in more detail below, below the substrate 110. Light which is incident onto the active layer ACT of the driving transistor DT is blocked by the light shielding layer LS to minimize a leakage current.

The buffer layer 111 is disposed on the substrate 110 and the light shielding layer LS. The buffer layer 111 may reduce permeation of moisture or impurities through the substrate 110. The buffer layer 111 may be configured by a single layer or a double layer of silicon oxide (SiOx) or silicon nitride (SiNx), but is not limited thereto. However, the buffer layer 111 may be omitted depending on a type of substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, a contact hole through which the source electrode SE and the drain electrode DE are connected to the active layer ACT is formed. The first interlayer insulating layer 113 and the second interlayer insulating layer 114 are insulating layers for protecting a component below the first interlayer insulating layer 113 and the second interlayer insulating layer 114 and may be configured by a single layer or a double layer of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

In the meantime, in one or more aspects of the present disclosure, it is described that the first interlayer insulating layer 113 and the second interlayer insulating layer 114, that is, a plurality of insulating layers is disposed between the gate electrode GE and the source electrode SE and the drain electrode DE. However, only one insulating layer may be disposed between the gate electrode GE and the source electrode SE and the drain electrode DE, but the present disclosure is not limited thereto.

Further, as illustrated in the drawings, when a plurality of insulating layers, such as the first interlayer insulating layer 113 and the second interlayer insulating layer 114, is disposed between the gate electrode GE and the source electrode SE and the drain electrode DE, an electrode may be further formed between the first interlayer insulating layer 113 and the second interlayer insulating layer 114. The additionally formed electrode may form a capacitor with the other configuration disposed below first interlayer insulating layer 113 or above the second interlayer insulating layer 114.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS may be minimized. Even though in the drawing, the light shielding layer LS is connected to the drain electrode DE, the light shielding layer LS may also be connected to the source electrode SE, but is not limited thereto.

The power line VSS is disposed on the second interlayer insulating layer 114. The power line VSS is electrically connected to the light emitting element ED together with the driving transistor DT to allow the light emitting element ED to emit light. The power line VSS may be configured by a conductive material such as copper (Cu), aluminum (Al), molybdenum (Mo), nickel (Ni), titanium (Ti), chrome (Cr), or an alloy thereof, but is not limited thereto.

The first planarization layer 115 is disposed on the driving transistor DT and the power line VSS. The first planarization layer 115 may planarize an upper portion of the substrate 110 on which the driving transistor DT is disposed. The first planarization layer 115 may be configured by a single layer or a double layer, and for example, may be formed of photoresist or an acrylic-based organic material, but is not limited thereto.

A plurality of reflective electrodes RE which is spaced apart from each other is disposed on the first planarization layer 115. The plurality of reflective electrodes RE electrically connects the light emitting diode ED to the power line VSS and the driving transistor DT and serves as a reflector which reflects light emitted from the light emitting diode ED to the upper portion of the light emitting diode ED. The plurality of reflective electrodes RE is formed of a conductive material having excellent reflecting property to reflect light emitted from the light emitting diode ED toward the upper portion of the light emitting diode ED.

The plurality of reflective electrodes RE may include various conductive layers in consideration of a light reflection efficiency and a resistance. For example, the plurality of reflective electrodes RE may use silver (Ag), aluminum (Al), molybdenum (Mo), titanium (Ti), or an alloy thereof, but is not limited thereto.

Referring to FIG. 2, the plurality of reflective electrodes RE includes a first reflective electrode RE1, a second reflective electrode RE2, a third reflective electrode RE3, and a fourth reflective electrode RE4 which are spaced apart from each other.

The first reflective electrode RE1, the second reflective electrode RE2, and the third reflective electrode RE3 of the plurality of reflective electrodes RE may be formed to have a shape corresponding to each of the plurality of sub-pixels SP. For example, the first reflective electrode RE1 is disposed in an area corresponding to the first sub-pixel SP1, the second reflective electrode RE2 is disposed in an area corresponding to the second sub-pixel SP2. Also, the third reflective electrode RE3 may be disposed in an area corresponding to the third sub-pixel SP3.

The first reflective electrode RE1 is disposed so as to overlap the first red light emitting diode EDR1 and the second red light emitting diode EDR2 of the first sub-pixel SP1. The first reflective electrode RE1 may reflect light emitted from the first red light emitting diode EDR1 and the second red light emitting diode EDR2 above the first reflective electrode RE1.

The second reflective electrode RE2 is disposed so as to overlap the first green light emitting diode EDG1 and the second green light emitting diode EDG2 of the second sub-pixel SP2. The second reflective electrode RE2 may reflect light emitted from the first green light emitting diode EDG1 and the second green light emitting diode EDG2 above the second reflective electrode RE2.

The third reflective electrode RE3 is disposed so as to overlap the first blue light emitting diode EDB1 and the second blue light emitting diode EDB2 of the third sub-pixel SP3. The third reflective electrode RE3 may reflect light emitted from the first blue light emitting diode EDB1 and the second blue light emitting diode EDB2 above the third reflective electrode RE3.

In the meantime, the first reflective electrode RE1, the second reflective electrode RE2, and the third reflective electrode RE3 may electrically connect the driving transistor DT and the plurality of light emitting diodes ED. The first reflective electrode RE1, the second reflective electrode RE2, and the third reflective electrode RE3 are connected to the source electrode SE or the drain electrode DE of the driving transistor DT through a contact hole CH2 formed in the first planarization layer 115 and may be also electrically connected to the plurality of light emitting diodes ED. For example, as illustrated in FIG. 3, the first reflective electrode RE1, the second reflective electrode RE2, and the third reflective electrode RE3 are connected to the drain electrode DE of the driving transistor DT, but are not limited thereto.

First, each of the first reflective electrode RE1, the second reflective electrode RE2, and the third reflective electrode RE3 may be electrically connected to a second electrode 125 and a second semiconductor layer 123 of a respective one of the plurality of first light emitting diodes ED1 through a fourth contact hole CH4 formed in the first area A1. At this time, the fourth contact hole CH4 may be formed in an area which does not overlap a respective one of the plurality of first light emitting diodes ED1 as illustrated in FIG. 3, but is not limited thereto.

Further, each of the first reflective electrode RE1, the second reflective electrode RE2, and the third reflective electrode RE3 may be electrically connected to a second electrode 135 and a second semiconductor layer 133 of a respective one of the plurality of second light emitting diodes ED2 in the second area A2. At this time, as illustrated in FIG. 3, each of the first reflective electrode RE1, the second reflective electrode RE2, and the third reflective electrode RE3 may be electrically connected to a second electrode 135 and a second semiconductor layer 133 of a respective one of the plurality of second light emitting diodes ED2 in an area which overlaps a corresponding one of the plurality of second light emitting diodes ED2. For example, in the second area A2, top surfaces of the first reflective electrode RE1, the second reflective electrode RE2, and the third reflective electrode RE3 may be exposed by the adhesive layer AD. The second electrodes 135 of the plurality of second light emitting diodes ED2 may be electrically connected to the reflective electrode RE disposed below the plurality of second light emitting diodes ED2.

Next, the fourth reflective electrode RE4, among the plurality of reflective electrodes RE, is disposed in an area adjacent to the plurality of sub-pixels SP to reflect light emitted from the plurality of sub-pixels SP above the fourth reflective electrode RE4. For example, the fourth reflective electrode RE4 may be disposed to be adjacent to the third sub-pixel SP3, but is not limited thereto. Further, in FIG. 2, the fourth reflective electrode RE4 is disposed so as not to overlap the plurality of light emitting diodes ED, but is not limited thereto.

The fourth reflection electrode RE4 electrically connects the power line VSS and the plurality of light emitting diodes ED. The fourth reflective electrode RE4 may be connected to the power line VSS through the first contact hole CH1 formed in the first planarization layer 115. Further, the fourth reflective electrode RE4 is electrically connected to the first electrodes 124 and the first semiconductor layers 121 of the plurality of first light emitting diodes ED1 and the first electrodes 134 and the first semiconductor layers 131 of the plurality of second light emitting diodes ED2 through the first connection electrode CE1 to be described below in more detail.

In the second area A2, the second conductive pattern PE2 is disposed on the plurality of reflective electrodes RE. For example, the second conductive pattern PE2 may be disposed on a reflective electrode RE on which the plurality of second light emitting diodes ED2 is disposed, among the first reflective electrode RE1, the second reflective electrode RE2, and the third reflective electrode RE3, among the plurality of reflective electrodes RE.

The second conductive pattern PE2 is disposed on the first reflective electrode RE1, the second reflective electrode RE2, and the third reflective electrode RE3 exposed by the first cover layer 117 and the adhesive layer AD. Therefore, the second conductive pattern PE2 may be electrically connected to top surfaces of the first reflective electrode RE1, the second reflective electrode RE2, and the third reflective electrode RE3 disposed therebelow. In the meantime, the second conductive pattern PE2 extends from the top surfaces of the first reflective electrode RE1, the second reflective electrode RE2, and the third reflective electrode RE3 to cover a side surface of the first cover layer 117 which encloses an open area of the first cover layer 117.

The second conductive pattern PE2 may be disposed in the second area A2 of the plurality of sub-pixels SP. Therefore, the second conductive pattern PE2 may be disposed so as to overlap the plurality of second light emitting diodes ED2, among the plurality of light emitting diodes ED. At this time, a bottom surface of the second conductive pattern PE2 is in contact with the reflective electrode RE and a top surface of the second conductive pattern PE2 may be in contact with the second electrodes 135 of the plurality of second light emitting diodes ED2. Therefore, the second conductive pattern PE2 is connected to the second electrodes 135 and the second semiconductor layers 133 of the plurality of second light emitting diodes ED2 to electrically connect the plurality of second light emitting diodes ED2 and the driving transistor DT.

The second conductive pattern PE2 may be formed of a conductive material. Further, the second conductive pattern PE2 may be formed of a material having reflectivity. For example, the second conductive pattern PE2 is formed of silver (Ag) or a silver (Ag) alloy, but is not limited thereto. Further, the second conductive pattern PE2 may be formed of any one of silver (Ag) paste, aluminum (Al) paste, gold (Au) paste, and copper (Cu) paste and use silver (Ag), aluminum (Al), molybdenum (Mo), titanium (Ti), or an alloy thereof, but is not limited thereto.

The adhesive layer AD is disposed on the plurality of reflective electrodes RE. The adhesive layer AD is disposed in the first area A1 of the plurality of sub-pixels SP. Therefore, the adhesive layer AD may fix the plurality of first light emitting diodes ED1, among the plurality of light emitting diodes ED onto the substrate 110.

In contrast, the adhesive layer AD is not disposed in an area which overlaps the plurality of second light emitting diodes ED2. For example, the adhesive layer AD exposes top surfaces of the first reflective electrode RE1, the second reflective electrode RE2, and the third reflective electrode RE3 in the second area A2. In the meantime, even though in FIG. 3, it is illustrated that the adhesive layer AD is not disposed in the entire second area A2, it is not limited thereto. Further, the adhesive layer AD may not be disposed only in an area which overlaps the second conductive pattern PE2 and the plurality of second light emitting diodes ED2.

The adhesive layer AD may planarize an upper portion of the plurality of reflective electrodes RE. For example, the adhesive layer AD covers an area between the plurality of reflective electrodes RE which is spaced apart from each other to planarize the upper portion of the plurality of reflective electrodes RE, but is not limited thereto.

The adhesive layer AD may be selected from any one of adhesive polymer, epoxy resist, UV resin, polyimide, acrylate, urethane, and polydimethylsiloxane (PDMS), but is not limited thereto.

In the meantime, in the adhesive layer AD, a third contact hole CH3 which allows the first connection electrode CE1 to be connected to the fourth reflective electrode RE4 and a fourth contact hole CH4 which allows the second connection electrode CE2 to be connected to the first reflective electrode RE1, the second reflective electrode RE2, and the third reflective electrode RE3 are formed.

The plurality of light emitting electrodes ED is disposed in each of the plurality of sub-pixels SP on the adhesive layer AD or the plurality of reflective electrodes RE. Each of the plurality of light emitting diodes ED may be an element which emits light by a current. The plurality of light emitting diodes ED may include light emitting diodes ED which emit red light, green light, and blue light and implement various colored light including white by a combination thereof. For example, the plurality of light emitting diodes ED may be light emitting diodes (LEDs) or micro LEDs, but is not limited thereto.

Referring to FIGS. 2 and 3, the first light emitting diode ED1 is disposed on the adhesive layer AD. The first light emitting diode ED1 is disposed in the first area A1 of the plurality of sub-pixels SP.

Referring to FIG. 3, each of the first light emitting diodes ED1 includes a first semiconductor layer 121, an emission layer 122, a second semiconductor layer 123, a first electrode 124, a second electrode 125, and an encapsulation layer 126.

The first semiconductor layer 121 of the first light emitting diode ED1 is disposed on the adhesive layer AD, and the second semiconductor layer 123 of the first light emitting diode ED1 is disposed on the first semiconductor layer 121. The first semiconductor layer 121 and the second semiconductor layer 123 may be layers formed by doping n-type and p-type impurities into a specific material. For example, the first semiconductor layer 121 and the second semiconductor layer 123 may be layers doped with n-type and p-type impurities into a material such as gallium nitride (GaN), indium aluminum phosphide (InAlP), or gallium arsenide (GaAs). Further, the p-type impurity may be magnesium (Mg), zinc (Zn), beryllium (Be), etc. and the n-type impurity may be silicon (Si), germanium, tin (Sn), etc., but is not limited thereto.

A width of the second semiconductor layer 123 may be smaller than a width of the first semiconductor layer 121. Therefore, the second semiconductor layer 123 of the first light emitting diode ED1 may be disposed to upwardly protrude from a top surface of the first semiconductor layer 121.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

A width of the emission layer 122 may be smaller than a width of the first semiconductor layer 121. Therefore, the emission layer 122 of the first light emitting diode ED1 may be disposed to upwardly protrude from a top surface of the first semiconductor layer 121.

First electrodes 124 of two or more first light emitting diodes ED1 are disposed on the first semiconductor layer 121. The first electrode 124 is an electrode which electrically connects the power line VSS and the first semiconductor layer 121. The first electrode 124 may be in contact with the first semiconductor layer 121 which is exposed from the emission layer 122 and the second semiconductor layer 123. For example, the first electrode 124 may be disposed to be adjacent to both end portions of a top surface of the first semiconductor layer 121 having a circular planar shape. A planar shape of the first electrode 124 may be a circle and/or an oval, but is not limited thereto. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 of the first light emitting diode ED1 is disposed on the second semiconductor layer 123. The second electrode 125 may be in contact with the second semiconductor layer 123. A planar shape of the second electrode 125 may be a circle and/or an oval, but is not limited thereto. The second electrode 125 is an electrode which electrically connects the driving transistor DT and the second semiconductor layer 123. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 126 which encloses the first semiconductor layer 121, the emission layer 122, the second semiconductor layer 123, the first electrode 124, and the second electrode 125 is disposed. The encapsulation layer 126 is formed of an insulating material to protect the first semiconductor layer 121, the emission layer 122, and the second semiconductor layer 123. In the encapsulation layer 126, contact holes which expose the first electrode 124 and the second electrode 125 are formed to electrically connect a first connection electrode CE1 and a second connection layer CE2 to the first electrode 124 and the second electrode 125, respectively.

Referring to FIGS. 2 and 3, the plurality of second light emitting diodes ED2 is disposed on the plurality of reflective electrodes RE. The plurality of second light emitting diodes ED2 is disposed in at least one or more sub-pixels SP, among the plurality of sub-pixels SP. For example, the plurality of second light emitting diodes ED2 may be disposed on at least one or more reflective electrodes RE of the first reflective electrode RE1, the second reflective electrode RE2, and the third reflective electrode RE3.

Referring to FIGS. 2 and 3 together, the second light emitting diode ED2 includes a first semiconductor layer 131, an emission layer 132, a second semiconductor layer 133, a first electrode 134, a second electrode 135, and an encapsulation layer 136.

The second semiconductor layers 133 of the second light emitting diodes ED2 is disposed on the plurality of reflective electrodes RE, and the second conductive pattern PE2 and the first semiconductor layer 131 of the second light emitting diode ED2 is disposed on the second semiconductor layer 133. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), or gallium arsenide (GaAs). Further, the p-type impurity may be magnesium (Mg), zinc (Zn), beryllium (Be), etc. and the n-type impurity may be silicon (Si), germanium, tin (Sn), etc., but is not limited thereto.

In the meantime, a width of the second semiconductor layer 133 may be smaller than a width of the first semiconductor layer 131. Therefore, the second semiconductor layer 133 of the second light emitting diode ED2 may be disposed to downwardly protrude from a bottom surface of the first semiconductor layer 131.

The emission layer 132 of the second light emitting diode ED2 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), etc., but is not limited thereto.

In the meantime, a width of the emission layer 132 may be smaller than a width of the first semiconductor layer 131. Therefore, the emission layer 132 of the second light emitting diode ED2 may be disposed to downwardly protrude from a bottom surface of the first semiconductor layer 131.

First electrodes 134 of two or more second light emitting diodes ED2 are disposed below the first semiconductor layer 131. The first electrode 134 is an electrode which electrically connects the power line VSS and the first semiconductor layer 131. The first electrode 134 may be in contact with the first semiconductor layer 131 which is exposed from the emission layer 132 and the second semiconductor layer 133. For example, the first electrode 134 may be disposed to be adjacent to both end portions of a bottom surface of the first semiconductor layer 131 having a circular planar shape. A planar shape of the first electrode 134 may be a circle and/or an oval, but is not limited thereto. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 of the second light emitting diode ED2 is disposed below the second semiconductor layer 133. The second electrode 135 may be in contact with the second semiconductor layer 133. A planar shape of the second electrode 135 may be a circle and/or an oval, but is not limited thereto. The second electrode 135 is an electrode which electrically connects the driving transistor DT and the second semiconductor layer 133. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 136 which encloses the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, contact holes which expose the first electrode 134 and the second electrode 135 are formed to electrically connect the first conductive pattern PE1 and the second conductive pattern PE2 to the first electrode 134 and the second electrode 135, respectively. In the meantime, the first red light emitting diode EDR1, the first green light emitting diode EDG1, and the first blue light emitting diode EDB1 have different shapes. Also, the second red light emitting diode EDR2, the second green light emitting diode EDG2, and the second blue light emitting diode EDB2 have different shapes. Each of the plurality of first light emitting diodes ED1 includes a first semiconductor layer 121, an emission layer 122, a second semiconductor layer 123, a first electrode 124, a second electrode 125, and an encapsulation layer 126, but shapes of some configurations may be different from each other. Further, each of the second light emitting diodes ED2 includes a first semiconductor layer 131, an emission layer 132, a second semiconductor layer 133, a first electrode 134, a second electrode 135, and an encapsulation layer 136, but shapes of some configurations may be different from each other.

For example, both a planar shape of the first semiconductor layer 121 of the first red light emitting diode EDR1 and a planar shape of the first semiconductor layer 131 of the second red light emitting diode EDR2 may be a circle. Both a planar shape of the first semiconductor layer 121 of the first green light emitting diode EDG1 and a planar shape of the first semiconductor layer 131 of the second green light emitting diode EDG2 may be an oval. Both a planar shape of the first semiconductor layer 121 of the first blue light emitting diode EDB1 and a planar shape of the first semiconductor layer 131 of the second blue light emitting diode EDB2 may be an oval. For example, a ratio of a major axis and a minor axis of the first blue light emitting diode EDB1 is different from a ratio of a major axis and a minor axis of the first green light emitting diode EDG1. Further, a ratio of a major axis and a minor axis of the second blue light emitting diode EDB2 is different from a ratio of a major axis and a minor axis of the second green light emitting diode EDG2, but is not limited thereto.

Further, the first red light emitting diode EDR1 and the second red light emitting diode EDR2 are formed with the same configuration but the laminating order of the second red light emitting diode EDR2 is opposite to the laminating order of the first red light emitting diode EDR1.

The first green light emitting diode EDG1 and the second green light emitting diode EDG2 are formed with the same configuration but the laminating order of the second green light emitting diode EDG2 is opposite to the laminating order of the first green light emitting diode EDG1. The first blue light emitting diode EDB1 and the second blue light emitting diode EDB2 are formed with the same configuration but the laminating order of the second blue light emitting diode EDB2 is opposite to the laminating order of the first blue light emitting diode EDB1.

The first cover layer 117 is disposed on the adhesive layer AD and the plurality of reflective electrodes RE. The first cover layer 117 covers the top surface of the adhesive layer AD and top surfaces of the first reflective electrodes RE1, the second reflective electrodes RE2, and the third reflective electrodes RE3 exposed from the adhesive layer AD and planarizes upper portions of the adhesive layer AD and the plurality of reflective electrodes RE. The first cover layer 117 may be configured by a single layer or a double layer, and for example, may be formed of photoresist or an acrylic-based organic material, but is not limited thereto.

In the first area A1, the first cover layer 117 may be disposed so as to enclose a side surface of the plurality of first light emitting diodes ED1. For example, the first cover layer 117 may be disposed so as to cover a lower side surface of the first semiconductor layer 121 extending from a bottom surface of the first semiconductor layer 121 of the plurality of first light emitting diodes ED1 on the adhesive layer AD. Therefore, the first cover layer 117 overlaps a part of side surfaces of the plurality of first light emitting diodes ED1 to fix and protect the plurality of first light emitting diodes ED1.

Specifically, in the first area A1, the first cover layer 117 may enclose at least a part of the side surface of the first semiconductor layer 121 disposed below the first electrode 124 of the plurality of first light emitting diodes ED1. Therefore, a thickness of the first cover layer 117 may be smaller than a thickness of the first semiconductor layer 121. For example, the top surface of the first cover layer 117 may be disposed below the emission layer 122.

In the second area A2, the first cover layer 117 may be disposed so as to enclose at least a part of a side surface of the plurality of second light emitting diodes ED2. For example, the first cover layer 117 may include an open area which encloses a part of the plurality of second light emitting diodes ED2. Referring to FIG. 3, in the open area of the first cover layer 117, a part of the plurality of second light emitting diodes ED2 may be disposed and the other part of the plurality of second light emitting diodes ED2 may be disposed on the first cover layer 117. For example, in the open area, the second electrode 135, the second semiconductor layer 133, and the emission layer 132 of the plurality of second light emitting diodes ED2 which protrudes downwardly from the first semiconductor layer 131 of the plurality of second light emitting diodes ED2 may be disposed. Therefore, the first cover layer 117 may enclose a side surface of the second semiconductor layer 133 and a side surface of the emission layer 132 extending from the bottom surface of the second semiconductor layer 133. In the meantime, when the first semiconductor layer 131 is disposed with a stepped structure and the first semiconductor layer 131 protrudes downwardly from the first electrode 134 in an area which overlaps the emission layer 132, the first cover layer 117 may enclose the side surface of the first semiconductor layer 131 disposed below the first electrode 134.

In the meantime, a width of the open area of the first cover layer 117 is smaller than a width of the first semiconductor layer 131 of the plurality of second light emitting diodes ED2 and is larger than a width of the second semiconductor layer 133 and the emission layer 132 of the plurality of second light emitting diodes ED2. Therefore, in the open area, side surfaces of the second semiconductor layer 133 and the emission layer 132 of the plurality of second light emitting diodes ED2 may be disposed to be spaced apart from the side surface of the first cover layer 117.

In the meantime, in the open area of the first cover layer 117, the second electrode 135 of the plurality of second light emitting diodes ED2 may be electrically connected to the second conductive pattern PE2. That is, the second electrode 135 of the plurality of second light emitting diodes ED2 may be in contact with the second conductive pattern PE2 disposed therebelow. Further, the first connection electrode CE1 and the first conductive pattern PE1 are disposed on the first cover layer 117.

The first connection electrode CE1 is an electrode which is disposed in each of the plurality of sub-pixels SP to electrically connect the light emitting diode ED and the power line VSS. The first connection electrode CE1 may be connected to the fourth reflective electrode RE4 through the third contact hole CH3 formed in the first cover layer 117 and the adhesive layer AD. Accordingly, the first connection electrode CE1 may be electrically connected to the power line VSS through the fourth reflective electrode RE4. Further, the first connection electrode CE1 may be electrically connected to the first electrode 124 of each of the plurality of first light emitting diodes ED1 in the first area A1 of the plurality of sub-pixels SP. Further, the first connection electrode CE1 may be electrically connected to the first electrode 134 of each of the plurality of second light emitting diodes ED2 in the second area A2 of the plurality of sub-pixels SP.

In the meantime, one first connection electrode CE1 is disposed in all the plurality of sub-pixels SP so that the first connection electrodes CE1 disposed in the plurality of sub-pixels SP are connected to each other, but is not limited thereto.

First, the first connection electrode CE1 is disposed on the first electrodes 124 of the plurality of first light emitting diodes ED1 among the plurality of light emitting diodes ED in the first area A1 to be in direct contact with the first electrodes 124 of the plurality of first light emitting diodes ED1. Accordingly, the first connection electrode CE1 may electrically connect the power line VSS to the first electrodes 124 and the first semiconductor layers 121 of the plurality of first light emitting diodes ED1.

Further, when the first cover layer 117 is disposed below the first electrodes 124 of the plurality of first light emitting diodes ED1, the first connection electrode CE1 may be disposed so as to enclose a part of the side surfaces of the plurality of first light emitting diodes ED1 exposed between the first electrodes 124 of the plurality of first light emitting diodes ED1 and the first cover layer 117.

Referring to FIG. 3, the first connection electrode CE1 is disposed below the first electrodes 134 of the plurality of second light emitting diodes ED2 among the plurality of light emitting diodes ED in the second area A2 to be electrically connected to the first electrodes 134 of the plurality of second light emitting diodes ED2.

In the meantime, the first connection electrode CE1 is connected to the first electrode 134 of the plurality of second light emitting diodes ED2 through the first conductive pattern PE1 disposed on the first connection electrode CE1.

The first conductive pattern PE1 is disposed between the first connection electrode CE1 and the first electrode 134 of the plurality of second light emitting diodes ED2 in the second area A2. The first conductive pattern PE1 is disposed so as to overlap the first electrode 134 of the plurality of second light emitting diodes ED2 and for example, the first conductive pattern PE1 may be disposed so as to enclose an open area of the first cover layer 117. Therefore, a bottom surface of the first conductive pattern PE1 may be in contact with the first connection electrode CE1 in an area which is adjacent to the open area of the first cover layer 117. Also, a top surface of the first conductive pattern PE1 may be in contact with the first electrode 134 of the plurality of second light emitting diodes ED2. Accordingly, the first conductive pattern PE1 electrically connects the first electrode 134 of the plurality of second light emitting diodes ED2 and the first connection electrode CE1 in the area which is adjacent to the open area and may be electrically connected to the power line VSS through the first connection electrode CE1 and the fourth reflective electrodes RE4.

The first conductive pattern PE1 may be formed of a conductive material. Further, the first conductive pattern PE1 may be formed of a material having reflectivity. For example, the first conductive pattern PE1 is formed of silver (Ag) or a silver (Ag) alloy, but is not limited thereto. Further, the first conductive pattern PE1 may be formed of any one of silver (Ag) paste, aluminum (Al) paste, gold (Au) paste, and copper (Cu) paste and use silver (Ag), aluminum (Al), molybdenum (Mo), titanium (Ti), or an alloy thereof, but is not limited thereto.

Further, the second conductive pattern PE2 and the first conductive pattern PE1 may be formed of the same material, but are not limited thereto.

The second cover layer 118 is disposed on the first connection electrode CE1 and the plurality of light emitting diodes ED. The second cover layer 118 may planarize an upper portion of the substrate 110 on which the plurality of light emitting diodes ED is disposed. The first cover layer 117 and the second cover layer 118 may be configured by a single layer or a double layer, and for example, may be formed of photo resist or an acrylic-based organic material, but is not limited thereto.

The second cover layer 118 is disposed above the first cover layer 117 to enclose a part of side surfaces of the plurality of first light emitting diodes ED1 and a part of side surfaces of the plurality of second light emitting diodes ED2.

First, the second cover layer 118 covers the side surfaces of the plurality of first light emitting diodes ED1 in the first area A1 to fix the plurality of first light emitting diodes ED1 onto the substrate 110 together with the adhesive layer AD. The top surface of the second cover layer 118 is disposed to be higher than at least the emission layer 122 of the plurality of first light emitting diodes ED1 and is equal to or lower than the top surface of the second semiconductor layer 123 of the plurality of first light emitting diodes ED1. For example, a top surface of the second cover layer 118 corresponding to the plurality of first light emitting diodes ED1 may be disposed between the top surface of the emission layer 122 and the top surface of the second semiconductor layer 123 of the plurality of first light emitting diodes ED1. Alternatively, the top surface of the second cover layer 118 corresponding to the plurality of first light emitting diodes ED1 may be disposed on the same plane as the top surface of the second semiconductor layer 123. Therefore, the second cover layer 118 may enclose side surfaces of the emission layer 122 and the second semiconductor layer 123 of the plurality of first light emitting diodes ED1 in the first area A1.

In the first area A1, the second cover layer 118 may be disposed so as to enclose at least a part of a side surface of the plurality of second light emitting diodes ED2. For example, the second cover layer 118 may include an open area corresponding to the second area A2. At this time, a width of the open area of the second cover layer 118 may be larger than a width of the open area of the first cover layer 117 and a width of the first semiconductor layer 131 of the plurality of second light emitting diodes ED2. Therefore, in the second area A2, the second cover layer 118 may enclose the first semiconductor layer 131 of the plurality of second light emitting diodes ED2 disposed above the first cover layer 117. In the meantime, in the second area A2, the side surface of the second cover layer 118 may be disposed to be spaced apart from the side surface of the first semiconductor layer 131 of the plurality of second light emitting diodes ED2, but is not limited thereto.

The second connection electrode CE2 is disposed on the second cover layer 118. The second connection electrode CE2 is an electrode for electrically connecting the plurality of first light emitting diodes ED1, among the plurality of light emitting diodes ED and the driving transistor DT. The second connection electrode CE2 is connected to the first reflective electrode RE1, the second reflective electrode RE2, and the third reflective electrode RE3 through the fourth contact hole CH4 formed in the second cover layer 118, the first cover layer 117, and the adhesive layer AD. Accordingly, the second connection electrode CE2 is electrically connected to any one of the source electrode SE and the drain electrode DE of the driving transistor DT through the first reflective electrode RE1, the second reflective electrode RE2, and the third reflective electrode RE3. The second connection electrode CE2 may be individually disposed in each of the plurality of sub-pixels SP. The second connection electrode CE2 connects the driving transistor DT and the plurality of first light emitting diodes ED1 through the plurality of reflective electrodes RE disposed in the plurality of sub-pixels SP, but is not limited thereto.

The second connection electrode CE2 may be disposed only in the first area A1 of the plurality of sub-pixels SP. Further, the second connection electrode CE2 may be connected to the second electrode 125 of each of the plurality of first light emitting diodes ED exposed by the second cover layer 118 in the first area A1. Accordingly, the second connection electrode CE2 may electrically connect the driving transistor DT to the second electrode 125 and the second semiconductor layer 123 of the plurality of light emitting diodes ED.

In the meantime, the second connection electrode CE2 may be disposed so as not to overlap the plurality of second light emitting diodes ED2 disposed in the second area A2. Even though in FIG. 3, it is illustrated that the second connection electrode CE2 is not disposed in the entire surface of the second area A2, the second connection electrode CE2 may not be disposed only in an area which overlaps the plurality of second light emitting diodes ED2.

A bank BB is disposed on the second connection electrode CE2 and the second cover layer 118. The bank BB may cover the top surface of the second cover layer 118 exposed from the connection electrode CE2. Further, the bank BB is disposed to be spaced apart from the plurality of light emitting diodes ED with a predetermined interval and at least partially overlaps the plurality of reflective electrodes RE. For example, the bank BB may cover the second cover layer 118 and a part of the second connection electrode CE2 formed in the contact holes of the second cover layer 118.

The bank BB may be formed of an opaque material to reduce color mixture between the plurality of sub-pixels SP and for example, may be formed of black resin, but is not limited thereto.

The bank BB may include an open area corresponding to the second area A2. The open area of the bank BB is disposed so as to overlap the open area of the second cover layer 118 and a width of the open area of the bank BB may be larger than a width of the open area of the first cover layer 117 and a width of the first semiconductor layer 131 of the plurality of second light emitting diodes ED2. Therefore, the bank BB may enclose the first semiconductor layer 131 of the plurality of second light emitting diodes ED2 in the second area A2. Further, in the second area A2, the side surface of the bank BB may be disposed on the same plane as the side surface of the second cover layer 118, but is not limited thereto.

The second planarization layer 119 is disposed on the first connection electrode CE1, the second connection electrode CE2, and the bank BB. The second planarization layer 119 is a layer for protecting components below the second planarization layer 119, and may be configured by a single layer or a double layer of transparent epoxy, silicon oxide (SiOx) or silicon nitride (SiNx), but is not limited thereto.

The second planarization layer 119 may be disposed so as to overlap at least a part of the plurality of light emitting diodes ED. For example, the second planarization layer 119 is disposed in the first area A1 to overlap only the plurality of first light emitting diodes ED1 among the plurality of light emitting diodes ED.

In the meantime, the second planarization layer 119 may include an open area corresponding to the second area A2. The open area of the second planarization layer 119 is disposed so as to overlap the open area of the second cover layer 118 and the open area of the bank BB. A width of the open area of the second planarization layer 119 may be larger than a width of the open area of the first cover layer 117 and a width of the first semiconductor layer 131 of the plurality of second light emitting diodes ED2. Therefore, in the open area of the second planarization layer 119, the side surface of the second planarization layer 119 may be disposed to be spaced apart from the side surface of the plurality of second light emitting diodes ED2, but is not limited thereto.

In the meantime, in the second area A2, the protection layer OL which encloses the plurality of second light emitting diodes ED2 may be disposed. The protection layer OL fills the open area of the first cover layer 117, the open area of the second cover layer 118, the open area of the bank BB, and the open area of the second planarization layer 119 and encloses the side surface and the top surface of the plurality of second light emitting diodes ED2. Therefore, the protection layer OL may fix and protect the plurality of second light emitting diodes ED2.

The protection layer OL may be formed of a transparent material having a refractive index similar to that of the second planarization layer 119 and may be formed of an ultra-violet (UV) curable material. For example, the protection layer OL may be formed of a photoresist or an acrylic-based organic material, or a transparent epoxy having a transmittance of 99%, but is not limited thereto.

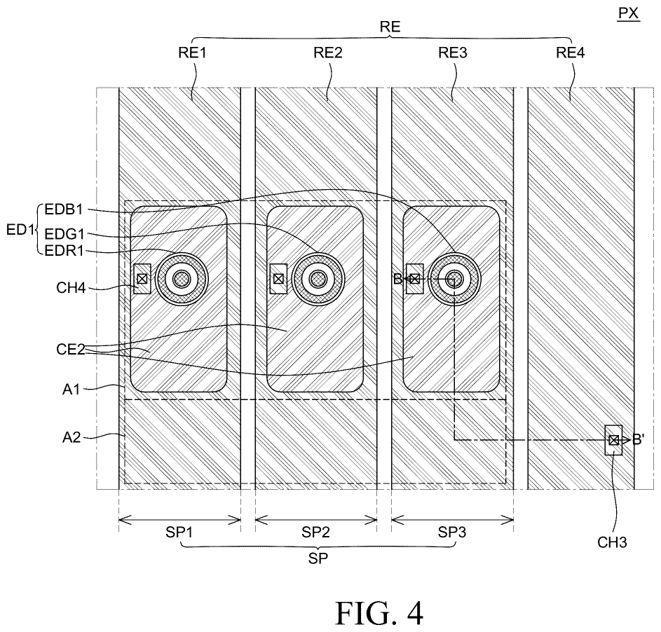

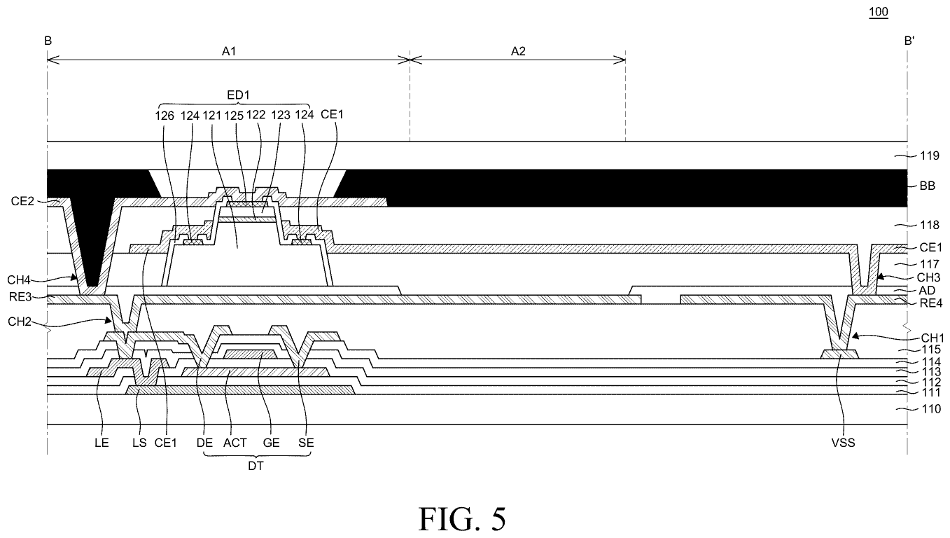

FIG. 4 is an enlarged plan view of a state before repairing a display device according to an example embodiment of the present disclosure. FIG. 5 is an example of a cross-sectional view taken along B-B′ of FIG. 4.

Referring to FIG. 4, each sub-pixel SP includes a plurality of first light emitting diodes ED1 disposed in the first area A1. A pixel PX is configured by a first sub-pixel SP1 in which a first red light emitting diode EDR1 is disposed, a second sub-pixel SP2 in which a first green light emitting diode EDG1 is disposed, and a third sub-pixel SP3 in which a first blue light emitting diode EDB1 is disposed.

In the second area A2 of the sub-pixel SP, top surfaces of the first reflective electrode RE1, the second reflective electrode RE2, and the third reflective electrode RE3 are exposed by the adhesive layer AD.

The first cover layer 117 is disposed on the adhesive layer AD and the plurality of reflective electrodes RE. The first cover layer 117 covers the overall second area A2 and covers top surfaces of the first reflective electrode RE1, the second reflective electrode RE2, and the third reflective electrode RE3 exposed by the adhesive layer AD.

The first connection electrode CE1 is disposed on the first cover layer 117 and the second cover layer 118, the bank BB, and the second planarization layer 119 are sequentially disposed on the first connection electrode CE1.

Thereafter, a lighting test for the plurality of first light emitting diodes ED1 disposed in the first area A1 of the plurality of sub-pixels SP may be performed.

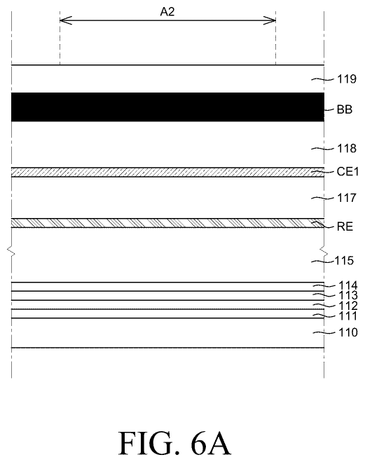

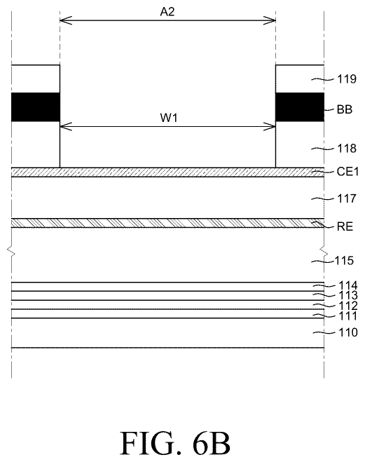

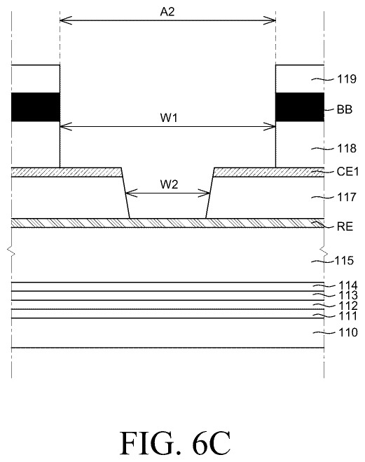

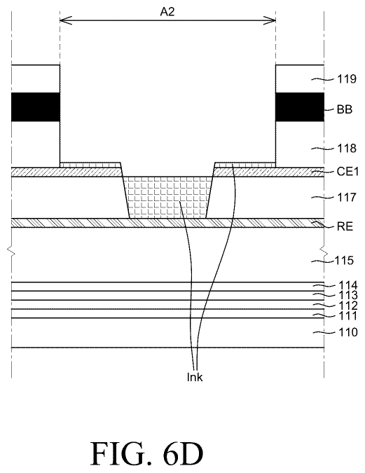

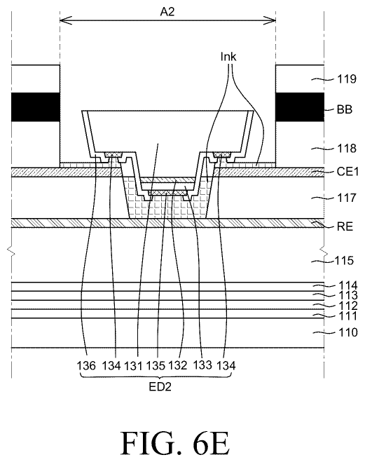

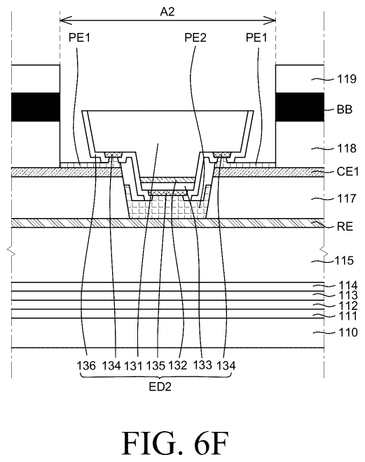

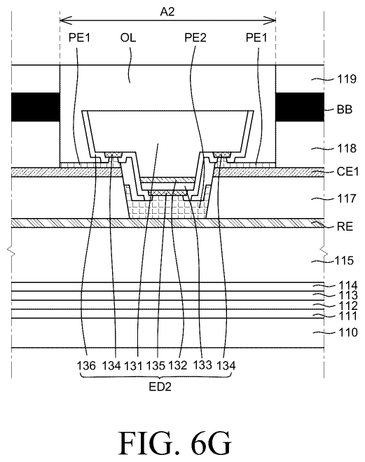

Hereinafter, a repair process will be described in more detail with reference to FIGS. 6A to 6F.

FIGS. 6A to 6G are process diagrams for explaining a forming process of a display device according to an example embodiment of the present disclosure.

Referring to FIG. 6A, in the second area A2 of the plurality of sub-pixels SP, the first cover layer 117 covers the top surface of the reflective electrode RE and the first connection electrode CE1, the second cover layer 118, the bank BB, and the second planarization layer 119 are sequentially disposed on the first cover layer 117.

Thereafter, a lighting test for the plurality of first light emitting diodes ED1 disposed in the first area A1 of the plurality of sub-pixels SP may be performed.

Next, the repair may be performed in a sub-pixel SP in which a defect occurs. Referring to FIG. 6B, in the second area A2 of the sub-pixel SP in which a defect occurs, the second cover layer 118, the bank BB, and the second planarization layer 119 which are disposed on the first connection electrode CE1 are removed. For example, the second cover layer 118, the bank BB, and the second planarization layer 119 disposed in the second area A2 are removed by a laser process and a part of the top surface of the first connection electrode CE1 disposed below the second cover layer 118 may be exposed. At this time, the laser process may be performed on a first width W1 which is larger than the width of the first semiconductor layer 131 of the plurality of second light emitting diodes ED2 to be disposed in the second area A2 and the top surface of the first connection electrode CE1 corresponding to the first width W1 is exposed.

Next, referring to FIG. 6C, an exposed part of the first connection electrode CE1 and a part of the first cover layer 117 disposed below the first connection electrode CE1 are removed. For example, a part of the first connection electrode CE1 and the first cover layer 117 which are disposed in the second area A2 is removed by the laser process. Therefore, a part of the top surface of the reflective electrode RE disposed below the first cover layer 117 may be exposed. At this time, the laser process may be performed on a second width W2 which is smaller than the width of the first semiconductor layer 131 of the plurality of second light emitting diodes ED2 to be disposed in the second area A2 and is larger than a width of the second semiconductor layer 133 of the plurality of second light emitting diodes ED2 and a width of the emission layer 132. The top surface of the reflective electrode RE corresponding to the second width W2 is exposed. Therefore, a stepped area is formed between the first cover layer 117 and the second cover layer 118, the bank BB, and the second planarization layer 119 and a top surface of the first connection electrode CE1 disposed on the first cover layer 117 is exposed in the stepped area.

Next, referring to FIG. 6D, a liquid metal ink Ink is applied on the reflective electrode RE exposed so as to correspond to the second width W2. The liquid metal ink Ink is disposed so as to cover a top surface of the reflective electrode RE and a top surface of the first connection electrode CE1 which are exposed. The liquid metal ink Ink may be a solution in which metal nanoparticles are dispersed. The liquid metal ink Ink may be one of a metal organic ion ink, a metal nanoparticle ink, a metal nanoparticle paste. When the liquid metal ink Ink is a silver paste, silver (Ag) nano particles may be uniformly dispersed in an organic solvent.

Next, referring to FIG. 6E, the second light emitting diode ED2 which is a repair light emitting diode is disposed on the liquid metal ink Ink in the stepped area. At this time, the second light emitting diode ED2 is a light emitting diode ED configured to emit light with the same color as the first light emitting diode ED1 which is disposed in a defective sub-pixel and has a structure which is laminated in a reverse order to the first light emitting diode ED1.

The second semiconductor layer 133 of the second light emitting diode ED2 has a smaller area than the first semiconductor layer 131 and is disposed below the first semiconductor layer 131. Therefore, the second semiconductor layer 133 of the second light emitting diode ED2 is disposed in the open area of the first cover layer 117 and the first semiconductor layer 131 of the second light emitting diode ED2 is disposed in the first cover layer 117 which encloses an open area. At this time, the second electrode 135 of the second light emitting diode ED2 is in contact with the liquid metal ink Ink disposed on the reflective electrode RE and the first electrode 134 of the second light emitting diode ED2 is in contact with the liquid metal ink Ink disposed on the first connection electrode CE1.

Next, a sintering process is performed on the liquid metal ink Ink. During the sintering process, a solvent included in the liquid metal ink Ink volatilizes. Therefore, after the sintering process, the first conductive pattern PE1 disposed on the first connection electrode CE1 and the second conductive pattern PE2 disposed on the reflective electrode RE are formed. As illustrated in FIG. 6F, the first conductive pattern PE1 electrically connects the first electrode 134 of the second light emitting diode ED2 and the first connection electrode CE1 and the second conductive pattern PE2 electrically connects the second electrode 135 of the second light emitting diode ED2 and the reflective electrode RE.

Next, referring to FIG. 6G, the protection layer OL is applied on the second light emitting diode ED2. The protection layer OL permeates between the side surface of the second light emitting diode ED2 and the side surface of the first cover layer 117, the side surface of the second cover layer 118, the side surface of the bank BB, and the side surface of the second planarization layer 119 to enclose the side surface of the second light emitting diode ED2. The protection layer OL is formed of an UV curable material. Therefore, the UV process is performed on the protection layer OL to fix and protect the second light emitting diodes ED2.

Generally, in the plurality of sub-pixels disposed on the substrate, a defective sub-pixel which does not normally emit light may be generated. For example, there may be a defective sub-pixel in which a light emitting diode itself is defective and/or the electrical connection between the light emitting diode and the transistor and/or between the light emitting diode and the power line is defective. At this time, the defective sub-pixel cannot emit light or the defective sub-pixel emits very weak light so that it is difficult to use the defective sub-pixel as a normal sub-pixel. Therefore, according to one approach, in each of the plurality of sub-pixels, two light emitting diodes which emit the same color are disposed to be used. For example, when the plurality of sub-pixels is configured by a red sub-pixel, a green sub-pixel, and a blue sub-pixel, two red light emitting diodes, two green light emitting diode, and two blue light emitting diodes are disposed on the substrate. Therefore, when any one of two light emitting diodes is defective, instead of the defective light emitting diode, another normal light emitting diode which emits light with the same color as the defective light emitting diode is driven. Therefore, for this approach, since twice as many light emitting diodes as the essential light emitting diodes are always needed to be placed in the display device, the manufacturing cost of the display device has increased. Further, the number of light emitting diodes disposed on the display panel is increased by twice, so that a process cost and a process procedure may be additionally requested to perform the lighting test for all the light emitting diodes.

In the display device 100 according to the example embodiment of the present disclosure, after a lighting test, the second light emitting diode ED2 which emits light with the same color as the first light emitting diode ED1 is transferred only to the sub-pixel SP in which a defective first light emitting diode ED1 occurs. Therefore, the repair is not performed on the sub-pixel SP which has the normal first light emitting diodes ED1, and only when a defect occurs, the second light emitting diode ED2, which is a repair light emitting element, is transferred so that the number of light emitting diodes ED disposed on the display device 100 may be reduced. Therefore, a process cost and a process procedure for performing the lighting test on the light emitting diodes ED may be reduced. Therefore, a manufacturing cost of the display device 100 may be saved.

Further, in the display device 100 according to the example embodiment of the present disclosure, the laser process is performed after the lighting test to locally perform the repair. During the repair process, in the second area A2 of the sub-pixel SP which is requested to be repaired, the second cover layer 118, the bank BB, and the second planarization layer 119 are open to expose the first connection electrode CE1 and a partial area of the first cover layer 117 is open to expose the reflective electrode RE. Next, the liquid metal ink Ink is applied on the first connection electrode CE1 and the reflective electrode RE to perform the repair only using the liquid metal ink Ink without using a separate repair line.

Further, in the display device 100 according to the example embodiment of the present disclosure, a stepped area corresponding to a shape of the second light emitting diode ED2 is formed in the first cover layer 117, the second cover layer 118, the bank BB, and the second planarization layer 119. Therefore, in the display device 100 according to the example embodiment of the present disclosure, during the repair process, the second light emitting diode ED2 may be stably fixed to the second area A2.

Further, in the display device 100 according to the example embodiment of the present disclosure, the first conductive pattern PE1 and the second conductive pattern PE2 are formed in the stepped area to suppress a short circuit between the first conductive pattern PE1 and the second conductive pattern PE2. That is, the second conductive pattern PE2 is disposed on the first cover layer 117, and the first connection electrode CE1 is disposed on the first conductive pattern PE1 to suppress a short circuit between the first conductive pattern PE1 and the second conductive pattern PE2.

Further, in the display device 100 according to the example embodiment of the present disclosure, the first conductive pattern PE1 and the second conductive pattern PE2 disposed in the stepped area are in contact with the first electrode 134 and the second electrode 135 of the second light emitting diode ED2, respectively, and improve a fixing strength of the second light emitting diode ED2. For example, when the first conductive pattern PE1 and the second conductive pattern PE2 are formed by sintering the liquid metal ink Ink, the adhesive force between the second light emitting diode ED2 and the reflective electrode RE and the first connection electrode CE1 is improved by the liquid metal ink Ink before sintering. Therefore, in a state in which the second light emitting diode ED2 is stably fixed, the liquid metal ink Ink is sintered so that the electrical connection of the second light emitting diode ED2 and the reflective electrode RE and the first connection electrode CE1 becomes stable. Further, the fixing strength of the second light emitting diode ED2 and the reflective electrode RE and the first connection electrode CE1 may be improved.

Further, in the display device 100 according to the example embodiment of the present disclosure, the second conductive pattern PE2 extends from the reflective electrode RE to cover the side surface of the first cover layer 117 which encloses the open area. Therefore, the second conductive pattern PE2 serves as a lateral surface reflector. When the emission layers 132 of the plurality of second light emitting diodes ED2 are disposed in the open area of the first cover layer 117, light emitted from the plurality of second light emitting diodes ED2 is reflected from the second conductive pattern PE2 to upwardly travel. Therefore, the problem in that the luminous efficiency of the display device 100 is reduced may be suppressed and the luminance is improved.

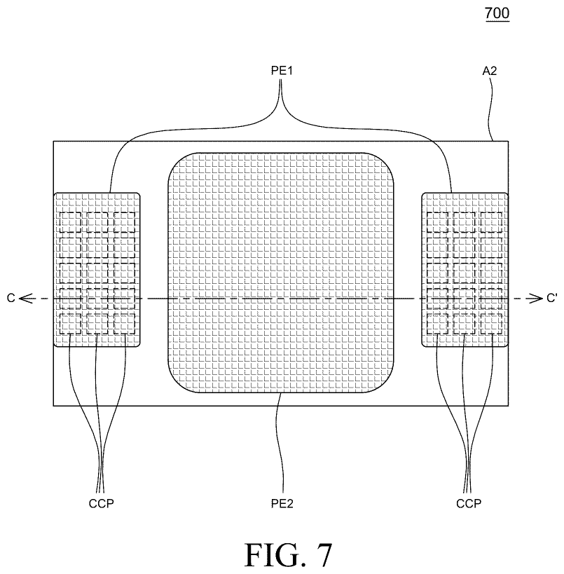

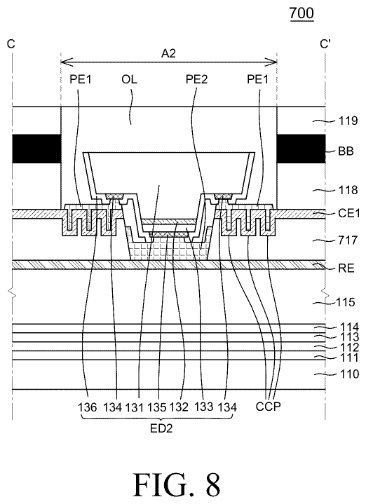

FIG. 7 is an enlarged plan view of a display device according to another example embodiment of the present disclosure. FIG. 8 is an example of a cross-sectional view taken along C-C′ of FIG. 7. In a display device 700 of FIGS. 7 and 8, only a first cover layer 717, a first conductive pattern PE1, and a first connection electrode CE1 are different from those of the display device 100 of FIGS. 1 to 6G, but other configurations are substantially the same so that a redundant description will be omitted for brevity.

Referring to FIG. 7, a first cover layer 717 is disposed on the plurality of reflective electrodes RE. The first cover layer 717 may cover top surfaces of the first reflective electrode RE1, the second reflective electrode RE2, and the third reflective electrode RE3 exposed by the adhesive layer AD.

The first cover layer 717 includes a plurality of concave patterns CCP. For example, the first cover layer 717 may include one or more concave patterns CCP which overlaps the first electrode 134 of the second light emitting diode ED2.

The first connection electrode CE1 is disposed on the first cover layer 717. The first connection electrode CE1 is disposed so as to overlap the first electrode 134 of the second light emitting diode ED2 and as illustrated in FIGS. 7 and 8, may be disposed on one or more concave patterns CCP. At this time, the first connection electrode CE1 may cover the concave pattern CCP of the first cover layer 717 and is disposed to be curved along a surface of the concave pattern CCP.

The first conductive pattern PE1 is disposed on the first connection electrode CE1. The first conductive pattern PE1 is disposed between the first connection electrode CE1 and the first electrode 134 of the plurality of second light emitting diodes ED2 in the second area A2. At this time, the first conductive pattern PE1 may cover the first connection electrode CE1 and fill one or more concave patterns CCP in which the first connection electrode CE1 is disposed. Even though in FIG. 8, it is illustrated that the first conductive pattern PE1 planarizes the surface of the curved first connection electrode CE1, it is not limited thereto.

In a display device 700 according to another example embodiment of the present disclosure, after the lighting test, the second light emitting diode ED2 which emits light with the same color as the first light emitting diode ED1 is transferred only to the sub-pixel SP in which a defective first light emitting diode ED1 occurs. Therefore, a process cost and a process procedure for performing the lighting test on the light emitting diodes ED may be reduced. Therefore, a manufacturing cost of the display device 700 may be saved.

Further, in the display device 700 according to another example embodiment of the present disclosure, the laser process is performed after the lighting test to expose the first connection electrode CE1 and the reflective electrode RE. Thereafter, the liquid metal ink Ink is applied on the exposed first connection electrode CE1 and reflective electrode RE to perform the repair without having a separate repair line.

Further, in the display device 700 according to another example embodiment of the present disclosure, the second light emitting diode ED2 is disposed in the stepped area of the first cover layer 717 and the second cover layer 118, the bank BB, and the second planarization layer 119 to stably fix the second light emitting diode ED2 in the second area A2.

Further, in the display device 700 according to another example embodiment of the present disclosure, the first conductive pattern PE1 and the second conductive pattern PE2 are formed in the stepped area to suppress a short circuit between the first conductive pattern PE1 and the second conductive pattern PE2.

Further, in the display device 700 according to another example embodiment of the present disclosure, the first conductive pattern PE1 and the second conductive pattern PE2 disposed in the stepped area are formed by sintering the liquid metal ink Ink to improve the fixing strength of the second light emitting diode ED2.

Further, in the display device 700 according to another example embodiment of the present disclosure, the second conductive pattern PE2 covers a side surface of the first cover layer 717 to serve as a lateral surface reflector to suppress the lowering of the luminous efficiency and improve the luminance.

Further, in the display device 700 according to another example embodiment of the present disclosure, the first cover layer 717 includes one or more concave patterns CCP which overlaps the first electrode 134 of the second light emitting diode ED2. Therefore, the first connection electrode CE1 and the first conductive pattern PE1 cover the concave pattern CCP which is disposed with a curved shape and an area of surface of the first connection electrode CE1 and the first conductive pattern PE1 disposed in the second area A2 may be improved. Therefore, even though the first conductive pattern PE1 is formed by silver paste having a relatively high specific resistance, the area of surface of the first conductive pattern PE1 is increased to reduce resistance and the increasing of the driving voltage of the second light emitting diode ED2 may be suppressed.

Further, in the display device 700 according to another example embodiment of the present disclosure, the first conductive pattern PE1 covers the concave pattern CCP disposed with a curved shape to increase a contact area between the first conductive pattern PE1 and the first cover layer 717. Therefore, a surface tension of the first conductive pattern PE1 may be improved and the problem in that the first conductive pattern PE1 is electrically connected to the second conductive pattern PE2 over the stepped area may be suppressed. Therefore, in the display device 700 according to another example embodiment of the present disclosure, a short circuit problem between the first conductive pattern PE1 and the second conductive pattern PE2 may be suppressed.

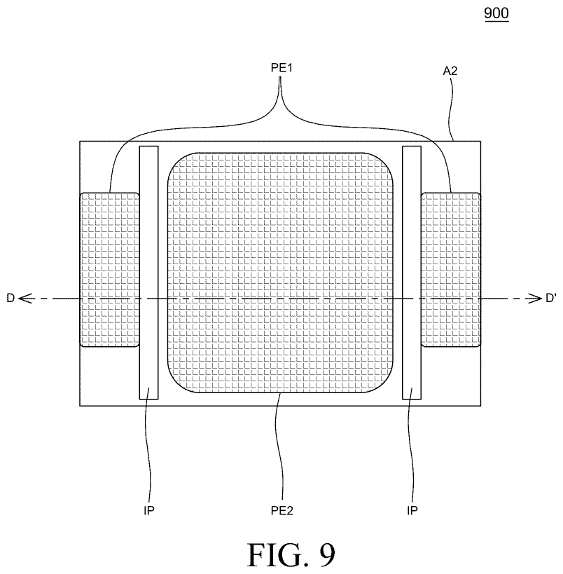

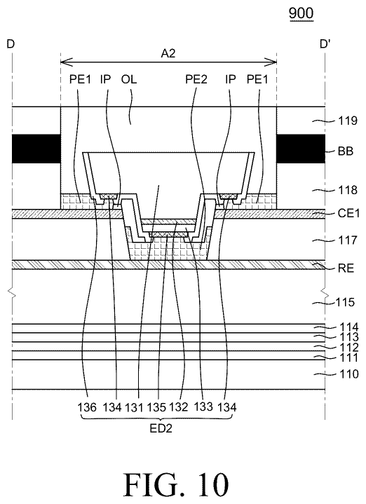

FIG. 9 is an enlarged plan view of a display device according to still another example embodiment of the present disclosure. FIG. 10 is an example of a cross-sectional view taken along D-D′ of FIG. 9. The only difference between the display device 900 of FIGS. 9 and 10 and the display device 100 of FIGS. 1 to 6G is that an insulating pattern IP is added, but the other configurations are substantially the same, so that a redundant description will be omitted for brevity.

Referring to FIGS. 9 and 10, an insulating pattern IP is disposed between the first conductive pattern PE1 and the second conductive pattern PE2. The insulating pattern IP separates the first conductive pattern PE1 from the second conductive pattern PE2 to suppress the short circuit of the first conductive pattern PE1 and the second conductive pattern PE2. For example, as illustrated in FIG. 10, the insulating pattern IP is disposed on the first connection electrode CE1 and is disposed to be adjacent to the open area, more than the first conductive pattern PE1. In one or more examples, compared to the first conductive pattern PE1, the insulating pattern IP is disposed closer to the open area. In the meantime, the position of the insulating pattern IP of FIGS. 9 and 10 is just illustrative, but is not limited thereto.

Even though in FIG. 10, it is illustrated that a top surface of the insulating pattern IP is in contact with a surface of the second light emitting diode ED, it is not limited thereto. Further, even though in FIG. 10, it is illustrated that one surface of the insulating pattern IP is in contact with one surface of the first conductive pattern PE1, it is not limited thereto.

The insulating pattern IP may be formed of an insulating material. For example, the insulating pattern IP may be formed of a photoresist or an acrylic-based organic material, but is not limited thereto. Further, the insulating pattern IP may be formed of a hydrophobic material. Therefore, when the first conductive pattern PE1 is formed from the liquid metal ink, the liquid metal ink is suppressed from overflowing the insulating pattern IP and the problem of electric connection of the first conductive pattern PE1 and the second conductive pattern PE2 may be suppressed.

Further, a cross-sectional shape of the insulating pattern IP may be a trapezoidal shape. Therefore, the side surface of the insulating pattern IP may be inclined with a top surface of the first connection electrode CE1 and form a relatively large contact angle with the first conductive pattern PE1.

In a display device 900 according to still another example embodiment of the present disclosure, after the lighting test, the second light emitting diode ED2 which emits light with the same color as the first light emitting diode ED1 is transferred only to the sub-pixel SP in which a defective first light emitting diode ED1 occurs. Therefore, a process cost and a process procedure for performing the lighting test on the light emitting diodes ED may be reduced. Therefore, a manufacturing cost of the display device 900 may be saved.

Further, in the display device 900 according to still another example embodiment of the present disclosure, the laser process is performed after the lighting test to expose the first connection electrode CE1 and the reflective electrode RE. Thereafter, the liquid metal ink Ink is applied on the exposed first connection electrode CE1 and reflective electrode RE to perform the repair without having a separate repair line.

Further, in the display device 900 according to still another example embodiment of the present disclosure, the second light emitting diode ED2 is disposed in the stepped area of the first cover layer 117 and the second cover layer 118, the bank BB, and the second planarization layer 119 to stably fix the second light emitting diode ED2 in the second area A2.

Further, in the display device 900 according to still another example embodiment of the present disclosure, the first conductive pattern PE1 and the second conductive pattern PE2 are formed in the stepped area to suppress a short circuit between the first conductive pattern PE1 and the second conductive pattern PE2.

Further, in the display device 900 according to still another example embodiment of the present disclosure, the first conductive pattern PE1 and the second conductive pattern PE2 disposed in the stepped area are formed by sintering the liquid metal ink Ink. Therefore, the fixing strength of the second light emitting diode ED2 may be improved.

Further, in the display device 900 according to still another example embodiment of the present disclosure, the second conductive pattern PE2 covers a side surface of the first cover layer 117 to serve as a lateral surface reflector to suppress the lowering of the luminous efficiency and improve the luminance. Therefore, in the display device 900 according to still another example embodiment of the present disclosure, an insulating pattern IP is disposed between the first conductive pattern PE1 and the second conductive pattern PE2. Therefore, the insulating pattern IP may suppress the first conductive pattern PE1 from overflowing to be connected to the second conductive pattern PE2. For example, when the first conductive pattern PE1 is formed with a liquid metal ink Ink, the liquid metal ink Ink may overflow the open area. Therefore, there is a problem in that the first conductive pattern PE1 and the second conductive pattern PE2 are electrically connected. Therefore, in the display device 900 according to still another example embodiment of the present disclosure, the insulating pattern IP is disposed on the first connection electrode CE1 to separate the first conductive pattern PE1 from the second conductive pattern PE2 and suppress the short circuit of the first conductive pattern PE1 and the second conductive pattern PE2.

In one or more examples, an element may include or may be one or more elements. In one or more examples, a reflective electrode may include or may be one or more reflective electrodes. In one or more examples, a reflective electrode RE may refer to one of the first, second, third and fourth reflective electrodes RE1, RE2, RE3 and RE4. In one or more examples, a reflective electrode RE may refer to the plurality of reflective electrodes RE.

In one or more examples, a first conductive pattern PE1 may include or may be one or more first conductive patterns PE1. In one or more examples, a second conductive pattern PE2 may include or may be one or more second conductive patterns PE2. In one or more examples, an open area may include or may be one or more open areas. In one or more examples, a contact hole may include or may be one or more contact holes. In one or more examples, an electrode may include or may be one or more electrodes. In one or more examples, a layer may include or may be one or more layers. In one or more examples, a space may include or may be one or more spaces. In one or more examples, a part may include or may be one or more parts.

Various examples and aspects of the present disclosure are described below. These are provided as examples, and do not limit the scope of the present disclosure.

According to one or more aspects of the present disclosure, there is provided a display device. The display device comprises a substrate, a plurality of pixels including a plurality of sub-pixels, a first cover layer which is disposed on the substrate and includes an open area, a plurality of first light emitting diodes which is disposed in or at the plurality of sub-pixels on the first cover layer and a second light emitting diode, which is disposed in one or more pixels among the plurality of pixels, on the substrate, wherein a part of a lower side of the second light emitting diode is disposed in the open area, a part of an upper side of the second light emitting diode is disposed on the first cover layer, and an area of a top surface of the second light emitting diode is larger than an area of a bottom surface of the second light emitting diode.

In one or more examples, an entire area of an entire top surface of the second light emitting diode is larger than an entire area of an entire bottom surface of the second light emitting diode.

Each of the plurality of first light emitting diodes and the second light emitting diode may include a first semiconductor layer, a second semiconductor layer having a width smaller than a width of the first semiconductor layer, an emission layer which may have a width smaller than a width of the first semiconductor layer and be disposed between the first semiconductor layer and the second semiconductor layer, a first electrode which may be in contact with the first semiconductor layer, and a second electrode which may be in contact with the second semiconductor layer, and a laminating order of the plurality of first light emitting diodes may be opposite to a laminating order of the second light emitting diode.

A width of the open area may be smaller than a width of the first semiconductor layer of the second light emitting diode and be larger than a width of the second semiconductor layer of the second light emitting diode.

The open area may enclose the second semiconductor layer and the emission layer of the second light emitting diode, and the first cover layer may enclose a part of the first semiconductor layer of the plurality of first light emitting diodes.

The display device may further comprise a reflective electrode which may be disposed below the first cover layer and overlap the plurality of first light emitting diodes and the second light emitting diode, wherein the open area may expose an area of the reflective electrode which may be disposed below the second light emitting diode, and the second electrode of the second light emitting diode may be electrically connected to the reflective electrode. The reflective electrode may comprise a plurality of reflective electrodes, each of the plurality of first light emitting diodes may be connected to a respective one of the plurality of reflective electrodes through a contact hole of the first cover layer, and the contact hole does not overlap a respective one of the plurality of first light emitting diodes.

The display device may further comprise a plurality of transistors disposed on the substrate, a plurality of power lines disposed on the substrate, and a first connection electrode which may be disposed on the first cover layer and be electrically connected to one of the plurality of transistors and the plurality of power lines, wherein the first electrodes of the plurality of first light emitting diodes and the first electrode of the second light emitting diode may be electrically connected to the first connection electrode.

The display device may further comprise a first conductive pattern which may electrically connect the first electrode of the second light emitting diode and the first connection electrode.

The first cover layer may include one or more concave patterns which overlap the first electrode of the second light emitting diode.

The first connection electrode may be disposed on the one or more concave patterns and the first conductive pattern fills the one or more concave patterns on which the first connection electrode may be disposed.

The display device may further comprise an insulating pattern which may be disposed adjacent to the open area and on the first connection electrode. Compared to the first conductive pattern, the insulating patter may be closer to the open area.

The display device may further comprise a reflective electrode which may overlap the plurality of first light emitting diodes and the second light emitting diode, and a second conductive pattern which may electrically connect the second electrode of the second light emitting diode and the reflective electrode in the open area, wherein the second conductive pattern may extend from the top surface of the reflective electrode to cover a side surface of the first cover layer which encloses the open area.

The display device may further comprise a second cover layer which may be disposed on the first cover layer to enclose a part of a side surface of the plurality of first light emitting diodes and a part of a side surface of the second light emitting diode, and a protection layer which may fill a space between the side surface of the second light emitting diode and the second cover layer.

The protection layer may include an ultra-violet (UV) curable material.

The second light emitting diode may be a normal light emitting diode. A first light emitting diode disposed in a same sub-pixel as the second light emitting diode may be a defective light emitting diode, wherein the first light emitting diode may be one of the plurality of first light emitting diodes, and the same sub-pixel may be one of the plurality of sub-pixels.

The display device may further comprise a reflective electrode disposed on the substrate, and an adhesive layer which may be disposed on the substrate and be in contact with a bottom surface of the plurality of first light emitting diodes, wherein a planar shape of the bottom surface of a first light emitting diode may be a circle or an oval, and wherein the first light emitting diode may be one of the plurality of first light emitting diodes.

According to one or more aspects of the present disclosure, there is provided a display device. The display device comprises a substrate, a plurality of pixels including a plurality of sub-pixels, a plurality of first light emitting diodes disposed on the substrate, wherein each of the plurality of first light emitting diodes is disposed in a respective one of the plurality of sub-pixels, and a second light emitting diode disposed on the substrate, wherein the second light emitting diode is disposed in one or more pixels among the plurality of pixels, wherein: a top layer of each of the plurality of first light emitting diodes comprises a conductive electrode, and a top layer of the second light emitting diode comprises a semiconductor layer and excludes a conductive electrode.

The second light emitting diode may have a side surface that extends outward from a lower portion of the side surface to an upper portion of the side surface.

Each of the plurality of first light emitting diodes may have a second side surface that extends inward from a lower portion of the second side surface to an upper portion of the second side surface.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a plurality of pixels including a plurality of sub-pixels;
a first cover layer which is disposed on the substrate and includes an open area;
a plurality of first light emitting diodes which is disposed at the plurality of sub-pixels on the first cover layer; and
a second light emitting diode, which is disposed in one or more pixels among the plurality of pixels, on the substrate,
wherein a part of a lower side of the second light emitting diode is disposed in the open area, a part of an upper side of the second light emitting diode is disposed on the first cover layer, and an area of a top surface of the second light emitting diode is larger than an area of a bottom surface of the second light emitting diode.

2. The display device according to claim 1, wherein each of the plurality of first light emitting diodes and the second light emitting diode includes:
a first semiconductor layer;
a second semiconductor layer having a width smaller than a width of the first semiconductor layer;
an emission layer which has a width smaller than a width of the first semiconductor layer and is disposed between the first semiconductor layer and the second semiconductor layer;
a first electrode which is in contact with the first semiconductor layer; and
a second electrode which is in contact with the second semiconductor layer; and
a laminating order of the plurality of first light emitting diodes is opposite to a laminating order of the second light emitting diode.

3. The display device according to claim 2, wherein a width of the open area is smaller than a width of the first semiconductor layer of the second light emitting diode and is larger than a width of the second semiconductor layer of the second light emitting diode.

4. The display device according to claim 2, wherein the open area encloses the second semiconductor layer and the emission layer of the second light emitting diode, and
wherein the first cover layer encloses a part of the first semiconductor layer of the plurality of first light emitting diodes.

5. The display device according to claim 2, further comprising:
a reflective electrode which is disposed below the first cover layer and overlaps the plurality of first light emitting diodes and the second light emitting diode,
wherein the open area exposes an area of the reflective electrode which is disposed below the second light emitting diode, and the second electrode of the second light emitting diode is for being electrically connected to the reflective electrode, and
wherein the reflective electrode comprises a plurality of reflective electrodes, each of the plurality of first light emitting diodes is connected to a respective one of the plurality of reflective electrodes through a contact hole of the first cover layer, and the contact hole does not overlap a respective one of the plurality of first light emitting diodes.

6. The display device according to claim 2, further comprising:
a plurality of transistors disposed on the substrate;
a plurality of power lines disposed on the substrate; and
a first connection electrode which is disposed on the first cover layer and is for being electrically connected to one of the plurality of transistors and the plurality of power lines,
wherein the first electrodes of the plurality of first light emitting diodes and the first electrode of the second light emitting diode are for being electrically connected to the first connection electrode.

7. The display device according to claim 6, further comprising:
a first conductive pattern for electrically connecting the first electrode of the second light emitting diode and the first connection electrode.

8. The display device according to claim 7, wherein the first cover layer includes one or more concave patterns which overlap the first electrode of the second light emitting diode.

9. The display device according to claim 8, wherein the first connection electrode is disposed on the one or more concave patterns, and the first conductive pattern fills the one or more concave patterns on which the first connection electrode is disposed.

10. The display device according to claim 7, further comprising:
an insulating pattern which is disposed adjacent to the open area on the first connection electrode,
wherein compared to the first conductive pattern, the insulating patter is closer to the open area.

11. The display device according to claim 6, further comprising:
a reflective electrode which overlaps the plurality of first light emitting diodes and the second light emitting diode; and
a second conductive pattern for electrically connecting the second electrode of the second light emitting diode and the reflective electrode in the open area,
wherein the second conductive pattern extends from the top surface of the reflective electrode to cover a side surface of the first cover layer which encloses the open area.

12. The display device according to claim 6, further comprising:
a second cover layer which is disposed on the first cover layer to enclose a part of a side surface of the plurality of first light emitting diodes and a part of a side surface of the second light emitting diode; and
a protection layer which fills a space between the side surface of the second light emitting diode and the second cover layer.

13. The display device according to claim 12, wherein the protection layer includes an ultra-violet curable material.

14. The display device according to claim 1, wherein the second light emitting diode is a normal light emitting diode,
wherein a first light emitting diode disposed in a same sub-pixel as the second light emitting diode is a defective light emitting diode,
wherein the first light emitting diode is one of the plurality of first light emitting diodes, and
wherein the same sub-pixel is one of the plurality of sub-pixels.

15. The display device according to claim 1, further comprising:
a reflective electrode disposed on the substrate; and
an adhesive layer which is disposed on the substrate and is in contact with a bottom surface of the plurality of first light emitting diodes,
wherein a planar shape of the bottom surface of a first light emitting diode is a circle or an oval, and
wherein the first light emitting diode is one of the plurality of first light emitting diodes.

16. A display device, comprising:
a substrate;
a plurality of pixels including a plurality of sub-pixels;
a plurality of first light emitting diodes disposed on the substrate, wherein each of the plurality of first light emitting diodes is disposed in a respective one of the plurality of sub-pixels; and
a second light emitting diode disposed on the substrate, wherein the second light emitting diode is disposed in one or more pixels among the plurality of pixels,
wherein:
a top layer of each of the plurality of first light emitting diodes comprises a conductive electrode; and
a top layer of the second light emitting diode comprises a semiconductor layer and excludes a conductive electrode.

17. The display device according to claim 16, wherein:
the second light emitting diode has a side surface that extends outward from a lower portion of the side surface to an upper portion of the side surface.

18. The display device according to claim 17, wherein:
each of the plurality of first light emitting diodes has a second side surface that extends inward from a lower portion of the second side surface to an upper portion of the second side surface.
